(19) United States
(12) Patent Application Publication
(10) Pub. No.: US 2024/0161832 A1
(43) Pub. Date: May 16, 2024

(54) SEMICONDUCTOR DEVICE RELATED TO PERFORMANCE OF A PROGRAM OPERATION AND METHOD OF OPERATING THE SEMICONDUCTOR DEVICE

(71) Applicant: SK hynix Inc., Icheon-si Gyeonggi-do (KR)

(72) Inventors: Hyung Jin CHOI, Icheon-si Gyeonggi-do (KR); Chan Hui JEONG, Icheon-si Gyeonggi-do (KR)

(73) Assignee: SK hynix Inc., Icheon-si Gyeonggi-do (KR)

(21) Appl. No.: 18/296,828

(22) Filed: Apr. 6, 2023

(30) Foreign Application Priority Data
Nov. 16, 2022 (KR) 10-2022-0153382

(51) Int. Cl. G11C 16/10; G11C 16/04; G11C 16/08; G11C 16/28

(52) U.S. Cl. CPC G11C 16/102; G11C 16/0433; G11C 16/08; G11C 16/28

(57) ABSTRACT

Provided herein is a semiconductor device and a method of operating the same. The semiconductor device includes first to n-th memory cell string groups, each including a plurality of memory cell strings, a peripheral circuit configured to sequentially perform program operations, each including a plurality of program loops, on the first to n-th memory cell string groups, and a program operation controller configured to control the peripheral circuit to apply a precharge voltage to a common source line and apply a turn-on voltage to one or more of a plurality of source select lines coupled to the first to n-th memory cell string groups in any one of the plurality of program loops, wherein a number of one or more source select lines to which the turn-on voltage is to be applied is determined based on a program loop count corresponding to of the one program loop.

### CROSS-REFERENCE TO RELATED APPLICATION

The present application claims priority under 35 U.S.C. § 119(a) to Korean patent application number 10-2022-0153382 filed on Nov. 16, 2022, in the Korean Intellectual Property Office, the entire disclosure of which is incorporated by reference herein.

### BACKGROUND

### 1. Technical Field

Various embodiments of the present disclosure generally relate to an electronic device, and more particularly to a semiconductor device related to performance of a program operation and a method of operating the semiconductor device.

### 2. Related Art

A memory system is a device which stores data under the control of a host device such as a computer or a smartphone. The memory system may include a memory device in which data is stored and a memory controller which controls the memory device. Memory devices are classified into a volatile memory device and a nonvolatile memory device.

The nonvolatile memory device may be a memory device in which stored data is retained even when the supply of power is interrupted. Examples of the nonvolatile memory device may include a read only memory (ROM), a programmable ROM (PROM), an electrically programmable ROM (EPROM), an electrically erasable and programmable ROM (EEPROM), and a flash memory.

A program operation is an operation of storing data in memory cells included in the nonvolatile memory device. The program operation may be implemented such that a program voltage apply operation of increasing the threshold voltages of memory cells and a verify operation of verifying the increased threshold voltages of the memory cells are repeatedly performed. Between the verify operation and the program voltage apply operation on the memory cells, voltages provided to the memory cells are discharged, wherein a phenomenon in which channel potentials of the memory cells are decreased to a negative state occurs. Accordingly, in order to increase the channel potentials of the memory cells before the program voltage apply operation is performed after the verify operation is terminated, the nonvolatile memory device may apply a certain voltage to a common source line.

### SUMMARY

An embodiment of the present disclosure may provide for a semiconductor device. The semiconductor device may include first to n-th memory cell string groups, each memory cell string group including a plurality of memory cell strings, a peripheral circuit configured to sequentially perform program operations, each program operation including a plurality of program loops, on the first to n-th memory cell string groups, and a program operation controller configured to control the peripheral circuit to apply a precharge voltage to a common source line and apply a turn-on voltage to one or more of a plurality of source select lines respectively coupled to the first to n-th memory cell string groups in any one of the plurality of program loops, wherein a number of one or more source select lines to which the turn-on voltage is to be applied is determined based on a program loop count corresponding to the one program loop.

An embodiment of the present disclosure may provide for a method of operating a semiconductor device. The method may include performing a plurality of program loops on a first memory cell string group among first to n-th memory cell string groups, each of the first to n-th memory cell string groups including a plurality of memory cell strings, applying a precharge voltage to a common source line in any one of the plurality of program loops, and applying a turn-on voltage to one or more source select lines, determined based on results of comparing a program loop count corresponding to the one program loop with reference count values, among a plurality of source select lines respectively coupled to the first to n-th memory cell string groups.

An embodiment of the present disclosure may provide for a semiconductor device. The semiconductor device may include a plurality of memory cell string groups, each including a plurality of memory cell strings, a peripheral circuit configured to perform a program operation including a plurality of program loops on a selected memory cell string group among the plurality of memory cell string groups, and a program operation controller configured to control the peripheral circuit such that a number of source select lines to which a turn-on voltage is to be applied, among a plurality of source select lines respectively coupled to the plurality of memory cell string groups, is increased in a precharge period in which a precharge voltage is applied to a common source line whenever a number of times that the plurality of program loops are performed equals each of reference count values during the program operation.

### BRIEF DESCRIPTION OF THE DRAWINGS

FIG. 1 is a diagram illustrating a memory system including a memory device according to an embodiment of the present disclosure.

FIG. 2 is a diagram illustrating threshold voltage distributions of memory cells depending on a program operation of a memory device.

FIG. 3 is a diagram illustrating a program operation of a memory device.

FIG. 4 is a diagram illustrating the structure of a memory block having a three-dimensional (3D) structure.

FIG. 5 is a diagram illustrating some of memory cell strings illustrated in FIG. 4.

FIG. 6 is a diagram illustrating others of the memory cell strings illustrated in FIG. 4.

FIG. 7 is a diagram illustrating a program voltage apply operation of a memory device.

FIG. 8 is a diagram illustrating a precharge period included in a program voltage apply operation of each of a plurality of program loops.

FIG. 9 is a diagram illustrating an example of a precharge period included in a program voltage apply operation of each of a plurality of program loops.

FIG. 10 is a flowchart illustrating a program voltage apply operation of a memory device.

FIG. 11 is a flowchart illustrating a method of determining the number of source select lines to which a turn-on voltage is to be applied.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms, and should not be construed as being limited to the embodiments described in the specification or application.

Various embodiments of the present disclosure are directed to a semiconductor device that is capable of improving threshold voltage distributions of memory cells during a program operation of the semiconductor device, and a method of operating the semiconductor device.

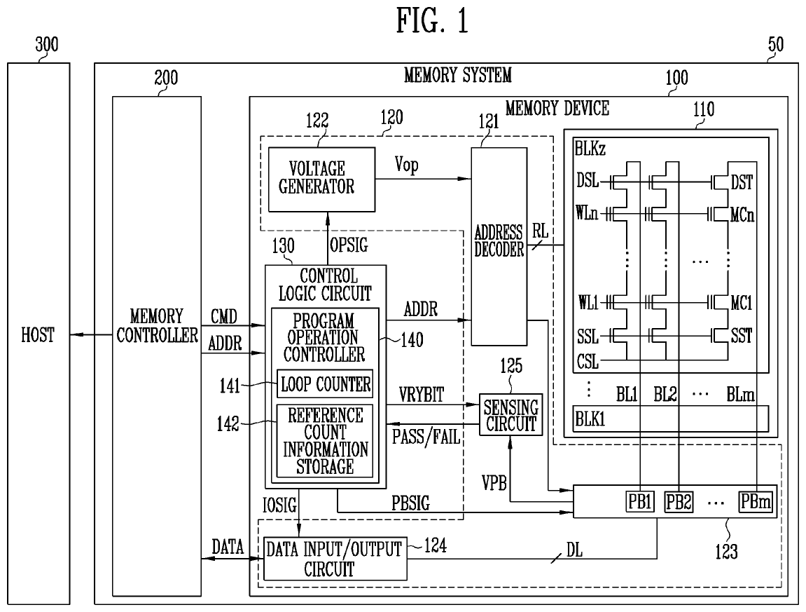

FIG. 1 is a diagram illustrating a memory system including a memory device according to an embodiment of the present disclosure.

Referring to FIG. 1, a memory system 50 may include a memory device 100 and a memory controller 200. The memory system 50 may be a device which stores data under the control of a host 300 such as a mobile phone or a computer. The memory system 50 may be manufactured as various types of storage devices such as a solid state drive (SSD) and a universal flash storage (UFS) depending on a host interface that is a scheme for communication with the host 300. The memory system 50 may be manufactured in various types of package forms such as a system-on-chip (SOC).

The memory device 100 may store data. The memory device 100 may be operated under the control of the memory controller 200. In an embodiment, the memory device 100 may be a nonvolatile memory device or a volatile memory device.

The memory device 100 may receive a command CMD and an address ADDR from the memory controller 200, and may access an area selected by the address ADDR. The memory device 100 may perform an operation indicated by the command CMD on the area selected by the address ADDR. For example, the memory device 100 may perform a write operation (i.e., a program operation), a read operation, and an erase operation. The memory device 100 may program data to the area selected by the address ADDR, or may read or erase data stored in the area selected by the address ADDR.

In an embodiment, the memory device 100 may include a memory cell array 110, a peripheral circuit 120, and a control logic circuit 130.

The memory cell array 110 may include a plurality of memory blocks BLK1 to BLKz. The plurality of memory blocks BLK1 to BLKz may be coupled to an address decoder 121 through row lines RL. The plurality of memory blocks BLK1 to BLKz may be coupled to a page buffer group 123 through bit lines BL1 to BLm. Each of the memory blocks BLK1 to BLKz may include a plurality of memory cells. In an embodiment, the plurality of memory cells may be nonvolatile memory cells.

In an embodiment, any one memory block BLKz, among the plurality of memory blocks BLK1 to BLKz, may include a plurality of word lines WL1 to WLn arranged in parallel between a drain select line DSL and a source select line SSL. The memory block BLKz may include a plurality of memory cell strings coupled between any one bit line and a common source line CSL. The bit lines BL1 to BLm may be coupled to the plurality of memory cell strings, respectively, and the common source line CSL may be coupled in common to the plurality of memory cell strings.

For example, the memory cell string may include a drain select transistor DST, a plurality of memory cells MC1 to MCn, and a source select transistor SST, which are coupled in series to each other between the common source line CSL and the first bit line BL1. One memory cell string may include at least one drain select transistor DST and at least one source select transistor SST.

A drain of the drain select transistor DST may be coupled to the first bit line BL1, and a source of the source select transistor SST may be coupled to the common source line CSL. The plurality of memory cells MC1 to MCn may be coupled in series between the drain select transistor DST and the source select transistor SST. Gates of the source select transistors SST included in different memory cell strings may be coupled to the source select line SSL, gates of the drain select transistors DST included in different memory cell strings ST may be coupled to the drain select line DSL, and gates of the memory cells MC1 to MCn may be coupled to the plurality of word lines WL1 to WLn, respectively. Memory cells coupled to the same word line, among the memory cells included in different memory cell strings, may be defined as a ‘physical page (PG)’. The memory block BLKz may include a number of physical pages identical to the number of word lines WL1 to WLn.

Each of the memory cells may be implemented as a single-level cell (SLC) capable of storing one bit of data, a multi-level cell (MLC) capable of storing two bits of data, a triple-level cell (TLC) capable of storing three bits of data, a quad-level cell (QLC) capable of storing four bits of data, or a memory cell capable of storing five or more bits of data.

One physical page may include data corresponding to a number of logical pages identical to the number of pieces of bit data that may be stored in each of memory cells. For example, when each memory cell is implemented as a triple-level cell, one physical page may include data corresponding to three logical pages.

The peripheral circuit 120 may drive the memory cell array 110. In an example, the peripheral circuit 120 may drive the memory cell array 110 so that a program operation, a read operation, and an erase operation are performed under the control of the control logic circuit 130. In an example, the peripheral circuit 120 may apply various operating voltages to the row lines RL and the bit lines BL1 to BLm or discharge the applied voltages under the control of the control logic circuit 130.

The peripheral circuit 120 may include the address decoder 121, a voltage generator 122, the page buffer group 123, a data input/output circuit 124, and a sensing circuit 125.

The address decoder 121 may be coupled to the memory cell array 110 through the row lines RL. The row lines RL may include drain select lines DSL, the plurality of word lines WL1 to WLn, source select lines SSL, and the common source line CSL.

The address decoder 121 may be operated in response to the control of the control logic circuit 130. The address decoder 121 may receive addresses ADDR from the control logic circuit 130.

The address decoder 121 may decode a block address, among the received addresses ADDR. The address decoder 121 may select at least one of the memory blocks BLK1 to BLKz according to the decoded block address. The address decoder 121 may decode a row address, among the received addresses ADDR. The address decoder 121 may select at least one word line WL of the selected memory block by applying voltages supplied from the voltage generator 122 to the at least one word line WL according to the decoded row address.

During a program operation, the address decoder 121 may apply a program voltage to the selected word line and apply a pass voltage having a level lower than that of the program voltage to unselected word lines. During a program verify operation, the address decoder 121 may apply a verify voltage to the selected word line and apply a verify pass voltage having a level higher than that of the verify voltage to unselected word lines.

The address decoder 121 may decode a column address among the received addresses ADDR. The decoded column address may be transferred to the page buffer group 123. In an embodiment, the address decoder 121 may include components such as a row decoder, a column decoder, and an address buffer.

The voltage generator 122 may generate a plurality of operating voltages Vop using an external supply voltage that is supplied to the memory device 100. The voltage generator 122 may be operated under the control of the control logic circuit 130.

In an embodiment, the voltage generator 122 may generate an internal supply voltage by regulating the external supply voltage. The internal supply voltage generated by the voltage generator 122 may be used as an operating voltage for the memory device 100.

In an embodiment, the voltage generator 122 may generate various operating voltages Vop that are used for program, read, and erase operations in response to an operation signal OPSIG. The voltage generator 122 may generate the plurality of operating voltages Vop using the external supply voltage or the internal supply voltage. The voltage generator 122 may generate various voltages required by the memory device 100. For example, the voltage generator 122 may generate a plurality of erase voltages, a plurality of program voltages, a plurality of pass voltages, a plurality of select read voltages, and a plurality of unselect read voltages.

The generated operating voltages Vop may be supplied to the memory cell array 110 by the address decoder 121.

The page buffer group 123 may include first to m-th page buffers PB1 to PBm. The first to m-th page buffers PB1 to PBm may be coupled to the memory cell array 110 through the first to m-th bit lines BL1 to BLm, respectively. The first to m-th page buffers PB1 to PBm may be operated under the control of the control logic circuit 130.

The first to m-th page buffers PB1 to PBm may transmit/receive data DATA to/from the data input/output circuit 124. During a program operation, the first to m-th page buffers PB1 to PBm may receive data DATA to be stored through the data input/output circuit 124 and data lines DL.

During a program operation, the first to m-th page buffers PB1 to PBm may transfer data DATA, received through the data input/output circuit 124, to selected memory cells through the bit lines BL1 to BLm. The memory cells in the selected page may be programmed based on the received data DATA. Memory cells coupled to a bit line to which a program-enable voltage (e.g., a ground voltage) is applied may have increased threshold voltages. The threshold voltages of memory cells coupled to a bit line to which a program-inhibit voltage (e.g., a supply voltage) is applied may be maintained. During a program verify operation, the first to m-th page buffers PB1 to PBm may read the data DATA stored in the selected memory cells from the selected memory cells through the bit lines BL1 to BLm.

The data input/output circuit 124 may be coupled to the first to m-th page buffers PB1 to PBm through the data lines DL. The data input/output circuit 124 may be operated under the control of the control logic circuit 130.

The data input/output circuit 124 may include a plurality of input/output buffers (not illustrated) which receive input data DATA. During a program operation, the data input/output circuit 124 may receive the data DATA to be stored from the memory controller 200.

During a program verify operation, the sensing circuit 125 may generate a reference current in response to an enable bit signal VRYBIT generated by the control logic circuit 130, and may output a pass signal or a fail signal to the control logic circuit 130 by comparing a sensing voltage VPB received from the page buffer group 123 with a reference voltage generated by the reference current. In an example, the sensing circuit 125 may output a pass signal to the control logic circuit 130 when the magnitude of the sensing voltage VPB is less than that of the reference voltage. In an example, the sensing circuit 125 may output a fail signal to the control logic circuit 130 when the magnitude of the sensing voltage VPB is greater than that of the reference voltage.

The control logic circuit 130 may be coupled to the address decoder 121, the voltage generator 122, the page buffer group 123, the data input/output circuit 124, and the sensing circuit 125. The control logic circuit 130 may control the overall operation of the memory device 100. The control logic circuit 130 may be operated in response to a command CMD received from the memory controller 200.

The control logic circuit 130 may control the peripheral circuit 120 by generating various types of signals in response to the command CMD and the address ADDR. For example, the control logic circuit 130 may generate the operation signal OPSIG, the addresses ADDR, a page buffer control signal PBSIG, and the enable bit signal VRYBIT in response to the command CMD and the address ADDR. The control logic circuit 130 may output the operation signal OPSIG to the voltage generator 122, may output the addresses ADDR to the address decoder 121, may output the page buffer control signal PBSIG to the page buffer group 123, and may output the enable bit signal VRYBIT to the sensing circuit 125. In addition, the control logic circuit 130 may determine whether a verify operation has passed or failed in response to the pass or fail signal PASS or FAIL output from the sensing circuit 125.

In an embodiment, the control logic circuit 130 may include a program operation controller 140. The program operation controller 140 may control a program operation performed on memory cells. The program operation may be an operation of storing data in the memory cells. In detail, the program operation may be an operation of increasing the threshold voltages of memory cells depending on the data to be stored in the memory cells. When the program operation is performed, each of the memory cells may have a threshold voltage corresponding to any one of a plurality of program states. The plurality of program states may be defined depending on the number of data bits stored in one memory cell. For example, when data is programmed according to a triple-level cell (TLC) scheme in which three bits of data are stored in one memory cell, the plurality of program states may indicate an erase state and first to seventh program states. After the program operation is performed, the threshold voltages of the memory cells may be determined depending on the data to be stored in the memory cells. Each of the memory cells may have any one of the plurality of program states as a target program state depending on the data to be stored in the corresponding memory cell.

In an embodiment, the program operation may include a plurality of program loops. Each program loop may include a program voltage apply operation and a verify operation. The program voltage apply operation may be an operation of increasing the threshold voltages of memory cells using a program voltage. The program voltage apply operation may include a precharge operation. The precharge operation may be an operation of increasing channel potentials of the plurality of memory cells. In detail, the precharge operation may apply a precharge voltage to the common source line CSL, and may be an operation of applying a turn-on voltage to the source select line SSL coupled to the memory cell string. The verify operation may be an operation of identifying, using a verify voltage, whether the threshold voltages of the memory cells have reached threshold voltages corresponding to a target program state.

In an embodiment, the program operation controller 140 may include a loop counter 141 and a reference count information storage 142. The loop counter 141 may count the number of times that the plurality of program loops are performed (i.e., a program loop count). The reference count information storage 142 may store information about reference count values. The reference count values may be a plurality of values.

In an embodiment, the program operation controller 140 may compare the program loop count with individual reference count values during a program operation. The program operation controller 140 may change the number of memory cell strings on which the precharge operation is to be performed depending on the results of comparing the program loop count with the individual reference count values. For example, the program operation controller 140 may increase the number of memory cell strings on which the precharge operation is to be performed whenever the program loop count reaches each of the reference count values.

The memory controller 200 may control the overall operation of the memory system 50.

The memory controller 200 may control the memory device 100 so that a write operation, a read operation or an erase operation is performed in response to a request received from the host 300. The memory controller 200 may provide a command, a physical block address or data to the memory device 100 depending on the write operation, the read operation or the erase operation.

In an embodiment, the memory controller 200 may internally generate a command, an address, and data regardless of whether a request from the host 300 is received, and may transmit them to the memory device 100. For example, the memory controller 200 may provide the memory device 100 with commands, addresses, and data required in order to perform read operations and write operations that are involved in performing wear leveling, read reclaim, garbage collection, etc.

The host 300 may communicate with the memory system 50 using various communication schemes such as a dual in-line memory module (DIMM).

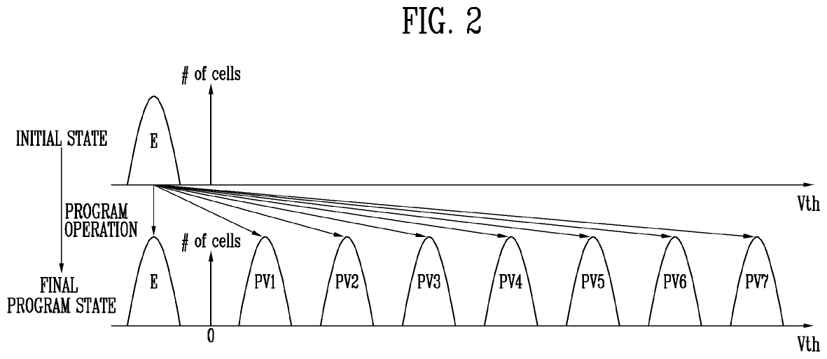

FIG. 2 is a diagram illustrating threshold voltage distributions of memory cells depending on a program operation of a memory device.

In FIG. 2, the horizontal axis of each graph indicates threshold voltages Vth of memory cells, and the vertical axis thereof indicates the number of memory cells (# of cells).

Referring to FIG. 2, the threshold voltage distribution of memory cells may change from an initial state to a final program state depending on the program operation.

In FIG. 2, a description is made on the assumption that data is programmed according to a TLC scheme in which one memory cell stores three bits of data.

The initial state may be a state in which a program operation is not performed and in which the threshold voltage distribution of memory cells is in an erase state E.

The final program state may be the threshold voltage distribution of memory cells on which the program operation is performed. The memory cells on which the program operation is performed may have threshold voltages corresponding to any one of a plurality of program states. For example, when data is programmed according to a triple-level cell (TLC) scheme in which three bits of data are stored in one memory cell, the plurality of program states may indicate the erase state E and first to seventh program states PV1 to PV7. In an embodiment, the memory cells on which the program operation is performed may have threshold voltages corresponding to any one of the erase state E and the first to seventh program states PV1 to PV7. The threshold voltage of each memory cell in the initial state may be increased to the threshold voltage corresponding to any one of the erase state E and the first to seventh program states PV1 to PV7 through the program operation.

Each memory cell may have any one of the erase state E and the first to seventh program states PV1 to PV7 as a target program state. The target program state may be determined depending on the data to be stored in the corresponding memory cell. Each memory cell may have a threshold voltage corresponding to the target program state, among the final program states, through the corresponding program operation.

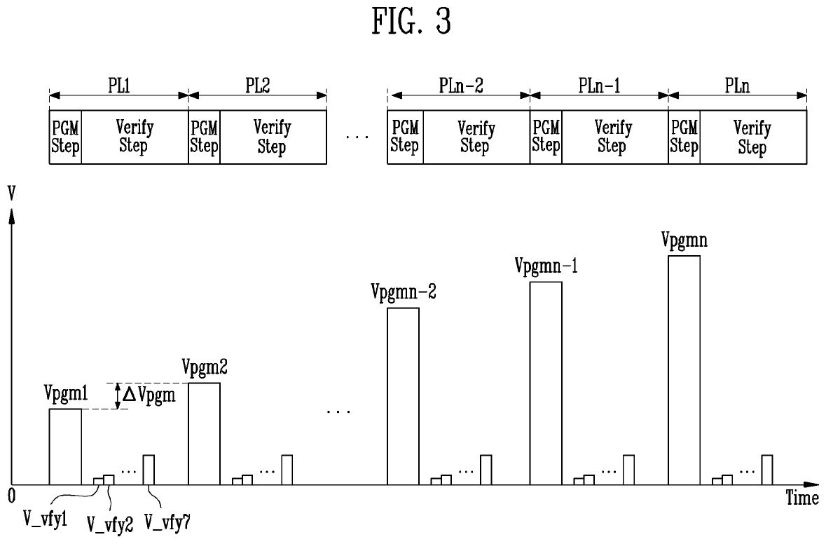

FIG. 3 is a diagram illustrating a program operation of a memory device.

In FIG. 3, the horizontal axis of a graph indicates time and the vertical axis thereof indicates voltage V applied to a word line. The voltage V applied to the word lines may include a program voltage Vpgm and a verify voltage V_vfy.

In FIG. 3, a description is made on the assumption that data is programmed according to a TLC scheme in which one memory cell stores three bits of data. However, the scope of the present disclosure is not limited thereto, and one memory cell may be programmed to store two or fewer bits of data or to store four or more bits of data.

Referring to FIG. 3, the program operation of the memory device 100 may include a plurality of program loops PL1 to PLn. The memory device 100 may perform a program operation so that each of selected memory cells coupled to a selected word line has a threshold voltage corresponding to any one of a plurality of program states by performing the plurality of program loops PL1 to PLn. For example, when one memory cell is programmed according to a TLC scheme, the memory device 100 may perform the program operation so that the memory cell has a threshold voltage corresponding to any one of an erase state E and first to seventh program states PV1 to PV7 by performing the plurality of program loops PL1 to PLn.

Each of the plurality of program loops PL1 to PLn may include a program voltage apply operation (PGM Step) and a verify operation (Verify Step). In an embodiment, each of the plurality of program loops PL1 to PLn executed for a program operation may correspond to a program loop count. For example, if it takes program loops PL1 to PL4 for all of the selected memory cells to have passed the verify operation (Verify Step) for a corresponding program state (i.e., any one of first to seventh program states PV1 to PV7) or erase state E, then the program loop count needed to pass the verify operation for the corresponding program state is four corresponding to the program loop PL4. For example, if the program operation being performed on selected memory cells for a corresponding program state (i.e. PV5) has completed program loops PL1 to PL9 and is currently performing program loop PL10, then the program loop count is ‘10’. For example, in an embodiment, the count value for the program loop PL10 of a program operation may be ten.

The program voltage apply operation (PGM Step) may be an operation of applying a program voltage to the selected word line coupled to the selected memory cells. For example, the memory device 100 may apply a first program voltage Vpgm1 to the selected word line coupled to selected memory cells in the first program loop PL1. After the first program voltage Vpgm1 is applied to the selected word line, respective threshold voltages of the selected memory cells may be the threshold voltages corresponding to target program states, among the plurality of program states.

The verify operation (Verify Step) may be an operation of applying a verify voltage to the selected word line coupled to the selected memory cells. The verify operation (Verify step) may be an operation of determining whether respective threshold voltages of the selected memory cells are threshold voltages corresponding to the target program states, among the plurality of program states. The verify operation (Verify Step) may be an operation of applying verify voltages corresponding to respective target program states of the selected memory cells.

In an embodiment, in the first program loop PL1, after the first program voltage Vpgm1 is applied to the selected word line coupled to the selected memory cells, the memory device 100 may apply first to seventh verify voltages V_vfy1 to V_vfy7 to the selected word line. In this case, the verify operation (Verify Step) may be performed on memory cells, having a first program state as a target program state, using the first verify voltage V_vfy1. The verify operation (Verify Step) may be performed on memory cells, having a second program state as the target program state, using the second verify voltage V_vfy2. The verify operation (Verify Step) may be performed on memory cells, having a third program state as the target program state, using the third verify voltage V_vfy3. The verify operation (Verify Step) may be performed on memory cells, having a fourth program state as the target program state, using the fourth verify voltage V_vfy4. The verify operation (Verify Step) may be performed on memory cells, having a fifth program state as the target program state, using the fifth verify voltage V_vfy5. The verify operation (Verify Step) may be performed on memory cells, having a sixth program state as the target program state, using the sixth verify voltage V_vfy6. The verify operation (Verify Step) may be performed on memory cells, having a seventh program state as the target program state, using the seventh verify voltage V_vfy7. The magnitudes of the verify voltages V_vfy1 to V_vfy7 may increase in the direction from the first verify voltage V_vfy1 to the seventh verify voltage V_vfy7. In detail, for the magnitudes of the verify voltages V_vfy1 to V_vfy7, the first verify voltage V_vfy1 may be the lowest, and the seventh verify voltage V_vfy7 may be the highest. The number of verify voltages is not limited to the present embodiment.

It may be determined that the memory cells having passed the verify operation (Verify Step) using respective verify voltages V_vfy1 to V_vfy7 have threshold voltages corresponding to the target program states. The memory cells having passed the verify operation (Verify Step) may be program-inhibited in the second program loop PL2. A program-inhibit voltage may be applied to the bit lines coupled to the program-inhibited memory cells.

It may be determined that the memory cells having failed in the verify operation (Verify Step) using respective verify voltages V_vfy1 to V_vfy7 do not have threshold voltages corresponding to the target program states. The memory cells having failed in the verify operation (Verify Step) may perform the second program loop PL2.

In the second program loop PL2, the memory device 100 may apply a second program voltage Vpgm2, higher than the first program voltage Vpgm1 by a unit voltage ΔVpgm, to the selected word line coupled to the selected memory cells. Thereafter, the memory device 100 may perform the verify operation (Verify Step) of the second program loop PL2 in the same manner as the verify operation (Verify Step) of the first program loop PL1.

Thereafter, the memory device 100 may perform a subsequent program loop in the same manner as the second program loop PL2 a preset number of times. The word “preset” as used herein with respect to a parameter, such as a preset number, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

In an embodiment, when the program operation is not completed within a preset number of program loops, the program operation may fail. When the program operation is completed within a preset number of program loops, the program operation may pass. Whether the program operation is completed may be determined depending on whether all of the selected memory cells have passed the verify operation (Verify Step). When all of the selected memory cells have passed the verify operation (Verify Step), a subsequent program loop might not be performed.

In an embodiment, the program voltage may be determined based on an incremental step pulse programming (ISPP) scheme. The level of the program voltage may be stepwise increased or decreased as the program loops PL1 to PLn are repeated. The number of times that program voltages used in each program loop are applied, the voltage levels of the program voltages, voltage apply times, etc. may be determined in various forms under the control of the memory controller 200.

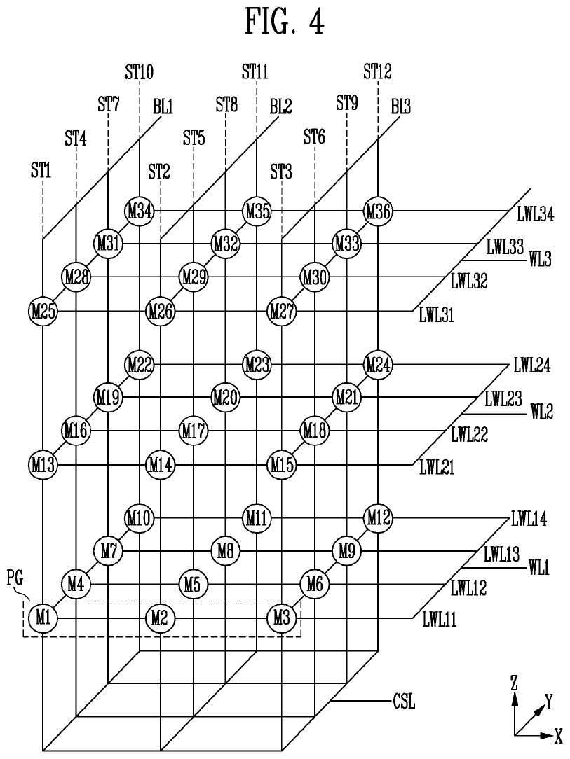

FIG. 4 is a diagram illustrating the structure of a memory block having a three-dimensional (3D) structure.

Referring to FIG. 4, the memory block may include a plurality of memory cells M1 to M36. The plurality of memory cells M1 to M36 may be coupled between bit lines BL1 to BL3 and a common source line CSL. One word line may be coupled in common to four local word lines. For example, the first word line WL1 may be coupled in common to eleventh to fourteenth local word lines LWL11 to LWL14. Memory cells may be coupled to each of the local word lines. A group of memory cells coupled to one local word line may form one physical page (PG). For example, first to third memory cells M1 to M3 coupled to the eleventh local word line LWL11 may form one physical page (PG). One word line may include a number of physical pages identical to the number of local word lines coupled in common thereto.

The number of local word lines coupled to one word line may be determined depending on the number of memory cell strings coupled in common to one bit line. For example, when four memory cell strings are coupled in common to one bit line, four local word lines may be coupled in common to one word line. In this case, one word line may include four physical pages (PG).

One memory cell string may include memory cells coupled in series to each other in a Z direction. For example, a first memory cell string ST1 may include a first memory cell M1, a thirteenth memory cell M13, and a 25-th memory cell M25. Memory cell strings in a Y direction may be coupled to one bit line. For example, the first memory cell string ST1, a fourth memory cell string ST4, a seventh memory cell string ST7, and a tenth memory cell string ST10 may be coupled to the first bit line BL1.

The numbers of word lines, local word lines, memory cell strings, bit lines, and memory cells, illustrated in FIG. 4, may be provided for convenience of description, and may be less than or greater than those illustrated in FIG. 4.

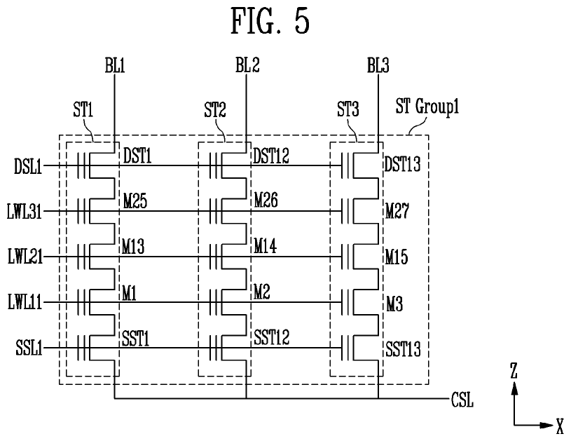

FIG. 5 is a diagram illustrating some of memory cell strings illustrated in FIG. 4.

In FIG. 5, a description will be made with reference to FIG. 4. Referring to FIG. 5, the first to third memory cell strings ST1 to ST3 may be coupled to the first to third bit lines BL1 to BL3, respectively. The first to third memory cell strings ST1, ST, and ST3 may include drain select transistors DST1, DST12, and DST13, respectively, coupled in common to a first drain select line DSL1. The first to third memory cell strings ST1, ST2, and ST3 may include source select transistors SST1, SST12, and SST13, respectively, coupled in common to a first source select line SSL1. Each memory cell string may include memory cells coupled to different local word lines, respectively. For example, the second memory cell string ST2 may include a second memory cell M2, a fourteenth memory cell M14, and a 26-th memory cell M26 coupled to an eleventh local word line LWL11, a 21-st local word line LWL21, and a 31-st local word line LWL31, respectively.

The plurality of memory cell strings coupled between the bit lines and the common source line CSL may form one memory cell string group. For example, the first to third memory cell strings ST1 to ST3 coupled to first to third bit lines BL1 to BL3, respectively, may form a first memory cell string group ST Group1. Similarly, the fourth to sixth memory cell strings ST4 to ST6 illustrated in FIGS. 4 to 6 may form a second memory cell string group. Also, seventh to ninth memory cell strings ST7 to ST9 may form a third memory cell string group, and tenth to twelfth memory cell strings ST10 to ST12 may form a fourth memory cell string group.

The plurality of memory cell strings included in one memory cell string group may be coupled to one drain select line and one source select line. The plurality of memory cell strings included in one memory cell string group may be coupled to different bit lines, respectively.

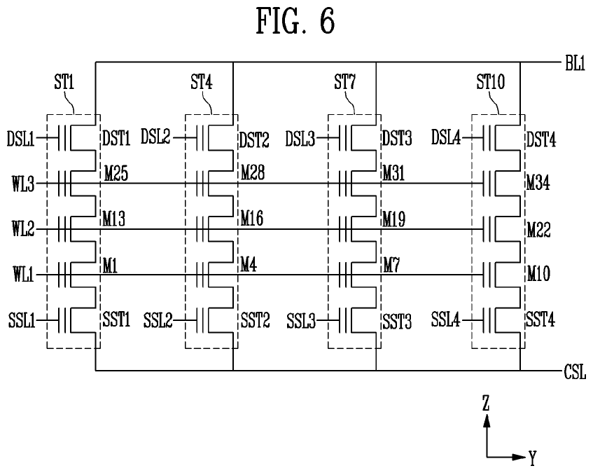

FIG. 6 is a diagram illustrating others of the memory cell strings illustrated in FIG. 4.

In FIG. 6, a description will be made with reference to FIGS. 4 and 5. Referring to FIG. 6, the first memory cell string ST1, the fourth memory cell string ST4, the seventh memory cell string ST7, and the tenth memory cell string ST10 may be coupled between the first bit line BL1 and the common source line CSL. Respective memory cell strings may be coupled to different drain select lines and different source select lines. For example, the first memory cell string ST1 may be coupled to the first drain select line DSL1 and the first source select line SSL1. The first drain select line DSL1 and the first source select line SSL1 may be coupled in common to the first to third memory cell strings ST1 to ST3. The fourth memory cell string ST4 may be coupled to the second drain select line DSL2 and the second source select line SSL2. The second drain select line DSL2 and the second source select line SSL2 may be coupled in common to the fourth to sixth memory cell strings ST4 to ST6. The seventh memory cell string ST7 may be coupled to the third drain select line DSL3 and the third source select line SSL3. The third drain select line DSL3 and the third source select line SSL3 may be coupled in common to the seventh to ninth memory cell strings ST7 to ST9. The tenth memory cell string ST10 may be coupled to the fourth drain select line DSL4 and the fourth source select line SSL4. The fourth drain select line DSL4 and the fourth source select line SSL4 may be coupled in common to the tenth to twelfth memory cell strings ST10 to ST12.

In an example, apart from the case illustrated in FIG. 6, the first to sixth memory cell strings ST1 to ST6 may be coupled in common to one source select line, and the seventh to twelfth memory cell strings ST7 to ST12 may be coupled in common to one source select line.

Each memory cell string may include memory cells coupled to different word lines, respectively. For example, the fourth memory cell string ST4 may include a fourth memory cell M4, a sixteenth memory cell M16, and a 28-th memory cell M28 coupled to the first word line WL1, the second word line WL2, and the third word line WL3, respectively.

Hereinafter, the program operation of the memory device 100 will be described in detail with reference to FIGS. 4 to 6. The memory device 100 may select the first word line WL1 during the program operation on the first to twelfth memory cells M1 to M12. Also, the memory device 100 may sequentially perform program operations on the first to third memory cells M1 to M3, the fourth to sixth memory cells M4 to M6, the seventh to ninth memory cells M7 to M9, and the tenth to twelfth memory cells M10 to M12. That is, because memory cells coupled in common to one local word line form one physical page, the memory device 100 may sequentially perform program operations on physical pages respectively included in the memory cell string groups.

In detail, the memory device 100 may select the eleventh local word line LWL11 by selecting the first drain select line DSL1 coupled in common to the first to third memory cell strings ST1 to ST3. The memory device 100 may perform a program operation on the first to third memory cells M1 to M3 by selecting the first word line WL1 and the first drain select line DSL1. The memory device 100 may perform a program operation on a physical page selected by one word line and one drain select line.

After performing the program operation on the first to third memory cells M1 to M3, the memory device 100 may select the twelfth local word line LWL12 by selecting the second drain select line DSL2 coupled in common to the fourth to sixth memory cell strings ST4 to ST6. The memory device 100 may perform a program operation on the fourth to sixth memory cells M4 to M6 by selecting the first word line WL1 and the second drain select line DSL2. In the same manner as the above description, the memory device 100 may sequentially perform a program operation on the seventh to ninth memory cells M7 to M9 and a program operation on the tenth to twelfth memory cells M10 to M12 by selecting the first word line WL1, the third drain select line DSL3, and the fourth drain select line DSL4.

Thereafter, the memory device 100 may sequentially perform program operations on the thirteenth to fifteenth memory cells M13 to M15, the sixteenth to eighteenth memory cells M16 to M18, the nineteenth to 21-st memory cells M19 to M21, and the 22-nd to 24-th memory cells M22 to M24 by selecting the second word line WL2.

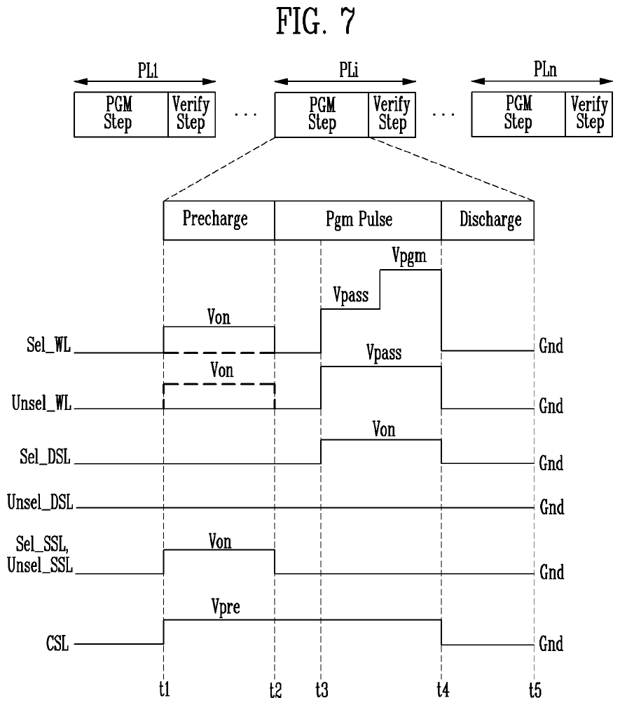

FIG. 7 is a diagram illustrating a program voltage apply operation of a memory device.

Referring to FIG. 7, the program operation may include a plurality of program loops PL1 to PLn. Each of the plurality of program loops PL1 to PLn may include a program voltage apply operation (PGM Step) and a verify operation (Verify Step). The program voltage apply operation (PGM Step) may include a precharge period (Precharge), a program pulse period (Pgm Pulse), and a discharge period (Discharge).

A period from t1 to t2 may be the precharge period. The precharge period may be a period during which channel potentials of memory cell strings are increased. In an embodiment, during the period from t1 to t2, the memory device 100 may apply a turn-on voltage Von to a selected word line Sel_WL. The turn-on voltage Von may be a voltage higher than a ground voltage Gnd. In an embodiment, during the period from t1 to t2, the memory device 100 may apply the ground voltage Gnd to the selected word line Sel_WL.

During the period from t1 to t2, the memory device 100 may apply the ground voltage Gnd to unselected word lines Unsel_WL. In an embodiment, during the period from t1 to t2, the memory device 100 may apply the turn-on voltage Von to word lines adjacent to the selected word line, among the unselected word lines Unsel_WL, and may apply the ground voltage Gnd to the remaining word lines, other than the adjacent word lines, among the unselected word lines Unsel_WL.

During the period from t1 to t2, the memory device 100 may apply the ground voltage Gnd to a selected drain select line and unselected drain select lines.

During the period from t1 to t2, the memory device 100 may apply the turn-on voltage Von to a selected source select line Sel_SSL and unselected source select lines Unsel_SSL. The turn-on voltage Von may be a voltage higher than threshold voltages of source select transistors coupled to the selected source select line Sel_SSL and the unselected source select lines Unsel_SSL, respectively.

During the period from t1 to t2, the memory device 100 may apply a precharge voltage Vpre to a common source line CSL. In an embodiment, the precharge voltage Vpre may be a voltage higher than the ground voltage Gnd. In an embodiment, the precharge voltage Vpre may be a supply voltage.

A period from t2 to t4 may be the program pulse period (Pgm Pulse). The program pulse period (Pgm Pulse) may be a period during which threshold voltages of selected memory cells are increased. During a period from t2 to t3, the memory device 100 may apply the ground voltage Gnd to the selected word line Sel_WL, the unselected word lines Unsel_WL, the selected source select line Sel_SSL, and the unselected source select lines Unsel_SSL.

During a period from t3 to t4, the memory device 100 may apply a pass voltage Vpass to the selected word line Sel_WL and thereafter apply a program voltage Vpgm thereto. During the period from t3 to t4, the memory device 100 may apply the pass voltage Vpass to the unselected word lines Unsel_WL. During the period from t3 to t4, the memory device 100 may apply the turn-on voltage Von to a selected drain select line Sel_DSL.

A period from t4 to t5 may be the discharge period (Discharge). During the period from t4 to t5, the memory device 100 may apply the ground voltage Gnd to the selected word line Sel_WL, the unselected word lines Unsel_WL, the selected drain select line Sel_DSL, and the common source line CSL.

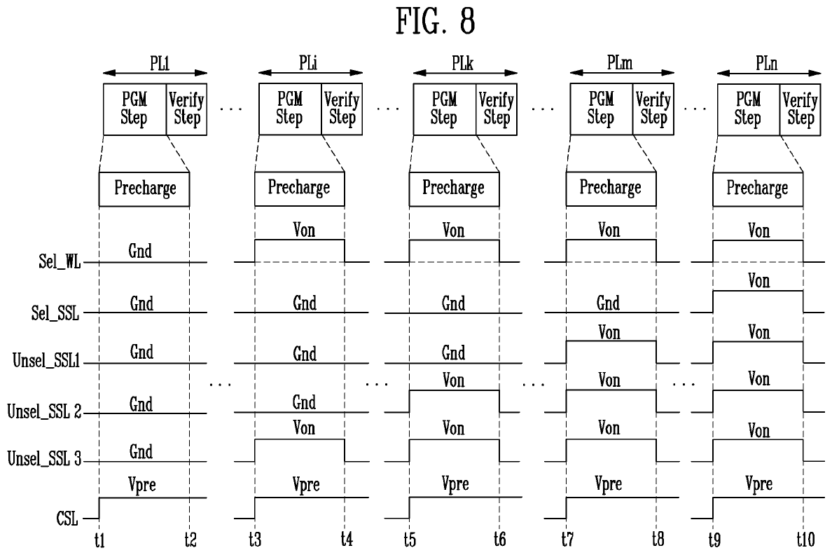

FIG. 8 is a diagram illustrating a precharge period included in a program voltage apply operation of each of a plurality of program loops.

Referring to FIG. 8, each of the plurality of program loops PL1 to PLn may include a program voltage apply operation (PGM Step) and a verify operation (Verify Step). In FIG. 8, only the precharge period (Precharge) included in the program voltage apply operation (PGM Step) of each of the program loops PL1 to PLn will be described.

In FIG. 8, the case where the program operation is performed on the first to third memory cells M1 to M3 illustrated in FIGS. 4 and 5 is described by way of example. In this case, referring to FIGS. 4 to 6, a selected word line Sel_WL may be a first word line WL1. A selected drain select line may be a first drain select line DSL1. A selected source select line Sel_SSL may be a first source select line SSL1. A first unselected source select line Unsel_SSL1 may be a second source select line SSL2. A second unselected source select line Unsel_SSL2 may be a third source select line SSL3. A third unselected source select line Unsel_SSL3 may be a fourth source select line SSL4.

A period from t1 to t2 may be a precharge period (Precharge) included in the program voltage apply operation (PGM Step) of the first program loop PL1. During the period from t1 to t2, the memory device 100 may apply the ground voltage Gnd to the selected word line Sel_WL, the selected source select line Sel_SSL, and the unselected source select lines Unsel_SSL1 to Unsel_SSL3. During the period from t1 to t2, the memory device 100 may apply a precharge voltage Vpre to a common source line CSL.

A period from t3 to t4 may be a precharge period (Precharge) included in the program voltage apply operation (PGM Step) of an i-th program loop PLi. During the period from t3 to t4, the memory device 100 may apply a turn-on voltage Von or the ground voltage Gnd to the selected word line Sel_WL. During the period from t3 to t4, the memory device 100 may apply the ground voltage Gnd to the selected source select line Sel_SSL and the first and second unselected source select lines Unsel_SSL1 and Unsel_SSL2. During the period from t3 to t4, the memory device 100 may apply the turn-on voltage Von to the third unselected source select line Unsel_SSL3. Referring to FIGS. 4 to 6, the third unselected source select line Unsel_SSL3 may be a source select line coupled to a fourth memory cell string group including tenth to twelfth memory cells. That is, the fourth memory cell string group coupled to the third unselected source select line Unsel_SSL3 may be a memory cell string group including a physical page on which a program operation is performed last.

A period from t5 to t6 may be a precharge period (Precharge) included in the program voltage apply operation (PGM Step) of a k-th program loop PLk. During the period from t5 to t6, the memory device 100 may apply the turn-on voltage Von to the second unselected source select line Unsel_SSL2 and the third unselected source select line Unsel_SSL3. Referring to FIGS. 4 to 6, the second unselected source select line Unsel_SSL2 may be a source select line coupled to a third memory cell string group including seventh to ninth memory cells. That is, the third memory cell string group coupled to the second unselected source select line Unsel_SSL2 may be a memory cell string group including a physical page on which a program operation is thirdly performed. In other words, the third memory cell string group coupled to the second unselected source select line Unsel_SSL2 may be a memory cell string group adjacent to the fourth memory cell string group.

A period from t7 to t8 may be a precharge period (Precharge) included in the program voltage apply operation (PGM Step) of an m-th program loop PLm. During the period from t7 to t8, the memory device 100 may apply the turn-on voltage Von to the first to third unselected source select lines Unsel_SSL1 to Unsel_SSL3. Referring to FIGS. 4 to 6, the first unselected source select line Unsel_SSL1 may be a source select line coupled to a second memory cell string group including fourth to sixth memory cells. That is, the second memory cell string group coupled to the first unselected source select line Unsel_SSL1 may be a memory cell string group including a physical page on which a program operation is secondly performed.

A period from t9 to t10 may be a precharge period (Precharge) included in the program voltage apply operation (PGM Step) of an n-th program loop PLn. During the period from t9 to t10, the memory device 100 may apply the turn-on voltage Von to the selected source select line Sel_SSL and the first to third unselected source select lines Unsel_SSL1 to Unsel_SSL3. Referring to FIGS. 4 to 6, the selected source select line Sel_SSL may be the first source select line SSL1, and the first to third unselected source select lines Unsel_SSL1 to Unsel_SSL3 may be source select lines coupled to the second to fourth memory cell string groups, respectively.

In an embodiment, the memory device 100 may determine the number of source select lines to which the turn-on voltage is to be applied based on a program loop count during the precharge period in which the precharge voltage is applied to the common source line and the turn-on voltage is applied to the source select line. In detail, the program operation controller 140 may determine the number of source select lines to which the turn-on voltage is to be applied based on the results of comparing the program loop count with reference count values.

In an embodiment, the memory device 100 may sequentially increase the number of source select lines to which the turn-on voltage is to be applied in the order of source select lines from a source select line, which is coupled to a memory cell string group including a physical page on which a program operation is performed last, to a source select line, which is coupled to a memory cell string group including a current physical page on which a program operation is being performed, whenever the program loop count reaches each of the reference count values. For example, before the program loop count reaches a first reference count value, the memory device 100 may apply the ground voltage to the plurality of source select lines before the program loop count reaches the first reference count value during the precharge period. When the program loop count reaches the first reference count value during the precharge period, the memory device 100 may apply the turn-on voltage to the third unselected source select line. For example, the first reference count value may be i. When the program loop count reaches a second reference count value greater than the first reference count value during the precharge period, the memory device 100 may apply the turn-on voltage to the second unselected source select line and the third unselected source select line. For example, the second reference count value may be k. When the program loop count reaches a third reference count value greater than the second reference count value during the precharge period, the memory device 100 may apply the turn-on voltage to the first unselected source select line, the second unselected source select line, and the third unselected source select line. For example, the third reference count value may be m. When the program loop count reaches a fourth reference count value greater than the third reference count value during the precharge period, the memory device 100 may apply the turn-on voltage to the selected source select line, the first unselected source select line, the second unselected source select line, and the third unselected source select line. For example, the fourth reference count value may be n.

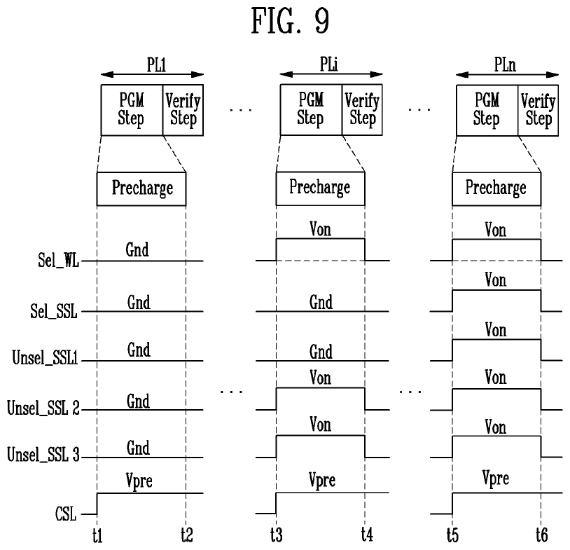

FIG. 9 is a diagram illustrating an example of a precharge period included in a program voltage apply operation of each of a plurality of program loops.

Repeated descriptions of configuration identical to that of FIG. 8 will be omitted in FIG. 9. Referring to FIG. 9, a program voltage apply operation (PGM Step) included in each of a plurality of program loops PL1 to PLn may include a precharge period (Precharge).

A period from t1 to t2 may be a precharge period (Precharge) included in the program voltage apply operation (PGM Step) of the first program loop PL1. During the period from t1 to t2, the memory device 100 may apply a ground voltage Gnd to a selected word line Sel_WL, a selected source select line Sel_SSL, and unselected source select lines Unsel_SSL1 to Unsel_SSL3. During the period from t1 to t2, the memory device 100 may apply a precharge voltage Vpre to a common source line CSL.

A period from t3 to t4 may be a precharge period (Precharge) included in the program voltage apply operation (PGM Step) of an i-th program loop PLi. During the period from t3 to t4, the memory device 100 may apply a turn-on voltage Von or the ground voltage Gnd to the selected word line Sel_WL. During the period from t3 to t4, the memory device 100 may apply the turn-on voltage Von to the second and third unselected source select lines Unsel_SSL2 and Unsel_SSL3.

A period from t5 to t6 may be a precharge period (Precharge) included in the program voltage apply operation (PGM Step) of an n-th program loop PLn. During the period from t5 to t6, the memory device 100 may apply the turn-on voltage Von to the selected source select line Sel_SSL and the first to third unselected source select lines Unsel_SSL1 to Unsel_SSL3.

In an embodiment, when the program loop count reaches each of the reference count values, the memory device 100 may increase the number of source select lines to which the turn-on voltage is to be applied, among the plurality of source select lines, during the precharge period, by 2 or more.

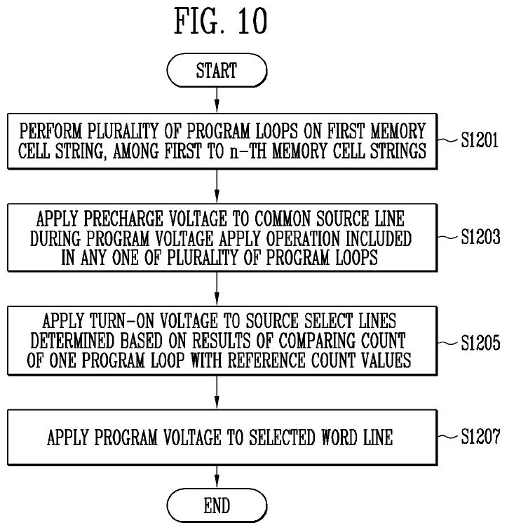

FIG. 10 is a flowchart illustrating a program voltage apply operation of a memory device.

Referring to FIG. 10, at step S1201, the memory device 100 may perform a plurality of program loops on a first memory cell string, among first to n-th memory cell strings. Each of the plurality of program loops may include a program voltage apply operation and a verify operation.

At step S1203, the memory device 100 may apply a precharge voltage to a common source line during the program voltage apply operation included in any one of the plurality of program loops.

At step S1205, the memory device 100 may apply a turn-on voltage to one or more source select lines determined based on the results of comparing the count of the one program loop (i.e., a program loop count) with one or more reference count values. In an embodiment, the memory device 100 may change the number of source select lines to which the turn-on voltage is to be applied, based on the results of comparing the count of the one program loop with the one or more reference count values.

At step S1207, the memory device 100 may apply a program voltage to a selected word line.

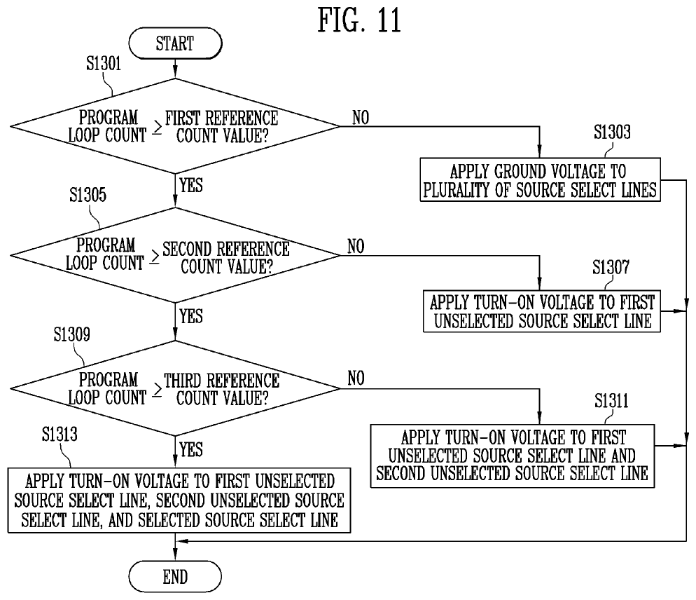

FIG. 11 is a flowchart illustrating a method of determining the number of source select lines to which a turn-on voltage is to be applied.

The method illustrated in FIG. 11 may be obtained by implementing step S1205 illustrated in FIG. 10. Referring to FIG. 11, at step S1301, the memory device 100 may determine whether the program loop count is greater than a first reference count value. When the program loop count is equal to or greater than the first reference count value, step S1305 may be performed. On the other hand, when the program loop count is less than the first reference count value, step S1303 may be performed.

At step S1303, when the program loop count is less than the first reference count value, the memory device 100 may apply a ground voltage to the plurality of source select lines. The plurality of source select lines may include a selected source select line and unselected source select lines.

At step S1305, the memory device 100 may determine whether the program loop count is greater than a second reference count value. The second reference count value may be a value greater than the first reference count value. When the program loop count is equal to or greater than the second reference count value, step S1309 may be performed. On the other hand, when the program loop count is less than the second reference count value, step S1307 may be performed.

At step S1307, when the program loop count is less than the second reference count value, the memory device 100 may apply a turn-on voltage to the first unselected source select line. A memory cell string group coupled to the first unselected source select line group may be a memory cell string group including a physical page on which a program operation is performed last.

At step S1309, the memory device 100 may determine whether the program loop count is greater than a third reference count value. The third reference count value may be a value greater than the second reference count value. When the program loop count is equal to or greater than the third reference count value, step S1313 may be performed. On the other hand, when the program loop count is less than the third reference count value, step S1311 may be performed.

At step S1311, when the program loop count is less than the third reference count value, the memory device 100 may apply the turn-on voltage to the first unselected source select line and the second unselected source select line. A memory cell string group coupled to the second unselected source select line may be a memory cell string group adjacent to the memory cell string group coupled to the first unselected source select line.

At step S1313, when the program loop count is equal to or greater than the third reference count value, the memory device 100 may apply the turn-on voltage to the first unselected source select line, the second unselected source select line, and the selected source select line.

In accordance with an embodiment the present disclosure, there are provided a semiconductor device that is capable of improving threshold voltage distributions of memory cells during a program operation of the semiconductor device, and a method of operating the semiconductor device.

What is claimed is:

1. A semiconductor device, comprising:
first to n-th memory cell string groups, each memory cell string group including a plurality of memory cell strings, where n is a natural number equal to or greater than 3;
a peripheral circuit configured to sequentially perform program operations, each program operation including a plurality of program loops, on the first to n-th memory cell string groups; and
a program operation controller configured to control the peripheral circuit to apply a precharge voltage to a common source line and apply a turn-on voltage to one or more of a plurality of source select lines respectively coupled to the first to n-th memory cell string groups in any one of the plurality of program loops,
wherein a number of one or more source select lines to which the turn-on voltage is to be applied is determined based on a program loop count corresponding to the one program loop.

2. The semiconductor device according to claim 1, wherein the program operation controller comprises:
a loop counter configured to count a number of times that the plurality of program loops are performed; and
a reference count information storage configured to store information about reference count values.

3. The semiconductor device according to claim 2, wherein the program operation controller is configured to determine the number of one or more source select lines to which the turn-on voltage is to be applied based on results of comparing the program loop count corresponding to the one program loop with the reference count values.

4. The semiconductor device according to claim 1, wherein the program operation controller is configured to control the peripheral circuit to apply the turn-on voltage to a first unselected source select line coupled to the n-th memory cell string group when the count value of the one program loop is equal to or greater than a first reference count value.

5. The semiconductor device according to claim 1, wherein the program operation controller is configured to control the peripheral circuit to apply the turn-on voltage to a first unselected source select line and a second unselected source select line that are coupled to the n-th memory cell string group and a memory cell string group adjacent to the n-th memory cell string group, respectively, when the count value of the one program loop is equal to or greater than a second reference count value.

6. The semiconductor device according to claim 1, wherein the program operation controller is configured to control the peripheral circuit to apply the turn-on voltage to a first unselected source select line, a second unselected source select line, and a selected source select line that are coupled to the n-th memory cell string group, a memory cell string group adjacent to the n-th memory cell string group, and the first memory cell string group, respectively, when the program loop count of the one program loop is equal to or greater than a third reference count value.

7. The semiconductor device according to claim 1, wherein the program operation controller is configured to control the peripheral circuit to apply one of the turn-on voltage and a ground voltage to a selected word line, among a plurality of word lines coupled to the first memory cell string group, while applying the turn-on voltage to the one or more source select lines.

8. The semiconductor device according to claim 1, wherein the program operation controller is configured to control the peripheral circuit to apply a ground voltage to a plurality of drain select lines coupled to the first to n-th memory cell string groups while applying the turn-on voltage to the one or more source select lines.

9. The semiconductor device according to claim 1, wherein the program operation controller is configured to control the peripheral circuit to apply the turn-on voltage to the one or more source select lines and thereafter apply a program voltage to a selected word line among a plurality of word lines coupled to the first memory cell string group.

10. The semiconductor device according to claim 9, wherein the program operation controller is configured to control the peripheral circuit to perform the program operation on the second memory cell string group after the program operation on the first memory cell string group is performed.

11. A method of operating a semiconductor device, comprising:
performing a plurality of program loops on a first memory cell string group among first to n-th memory cell string groups, each of the first to n-th memory cell string groups including a plurality of memory cell strings, where n is a natural number equal to or greater than 3;
applying a precharge voltage to a common source line in any one of the plurality of program loops; and
applying a turn-on voltage to one or more source select lines, determined based on results of comparing a program loop count corresponding to the one program loop with reference count values, among a plurality of source select lines respectively coupled to the first to n-th memory cell string groups.

12. The method according to claim 11, wherein applying the turn-on voltage to the one or more source select lines comprises:
when the program loop count corresponding to the one program loop is equal to or greater than a first reference count value, applying the turn-on voltage to a first unselected source select line coupled to the n-th memory cell string group.

13. The method according to claim 11, wherein applying the turn-on voltage to the one or more source select lines comprises:
when the count value of the one program loop is equal to or greater than a second reference count value, applying the turn-on voltage to a first unselected source select line and a second unselected source select line that are coupled to the n-th memory cell string group and a memory cell string group adjacent to the n-th memory cell string group, respectively.

14. The method according to claim 11, wherein applying the turn-on voltage to the one or more source select lines comprises:
when the count value of the one program loop is equal to or greater than a third reference count value, applying the turn-on voltage to a first unselected source select line, a second unselected source select line, and a selected source select line that are coupled to the n-th memory cell string group, a memory cell string group adjacent to the n-th memory cell string group, and the first memory cell string group, respectively.

15. The method according to claim 11, further comprising:
applying one of the turn-on voltage and a ground voltage to a selected word line, among a plurality of word lines coupled to the first memory cell string group, while applying the turn-on voltage to the one or more source select lines.

16. The method according to claim 11, further comprising:
applying a ground voltage to a plurality of drain select lines coupled to the first to n-th memory cell string groups while applying the turn-on voltage to the one or more source select lines.

17. The method according to claim 11, further comprising:
applying the turn-on voltage to a selected word line and word lines adjacent to the selected word line, among a plurality of word lines coupled to the first to n-th memory cell string groups, and applying a ground voltage to word lines, other than the selected word line and the adjacent word lines, among the plurality of word lines, while applying the turn-on voltage to the one or more source select lines.

18. The method according to claim 11, further comprising:
applying the turn-on voltage to the one or more source select lines and thereafter applying a program voltage to a selected word line among a plurality of word lines coupled to the first memory cell string group.

19. The method according to claim 18, further comprising:
performing the program operation on the second memory cell string group after the program operation on the first memory cell string group is performed.

20. A semiconductor device, comprising:
a plurality of memory cell string groups, each including a plurality of memory cell strings;
a peripheral circuit configured to perform a program operation including a plurality of program loops on a selected memory cell string group among the plurality of memory cell string groups; and
a program operation controller configured to control the peripheral circuit such that a number of source select lines to which a turn-on voltage is to be applied, among a plurality of source select lines respectively coupled to the plurality of memory cell string groups, is increased in a precharge period in which a precharge voltage is applied to a common source line whenever a number of times that the plurality of program loops are performed equals to each of reference count values during the program operation.
